(19) United States
(12) Patent Application Publication
(10) Pub. No.: US 2024/0113179 A1
(43) Pub. Date: Apr. 4, 2024

(54) SIC-BASED ELECTRONIC DEVICE WITH IMPROVED BODY-SOURCE COUPLING, AND MANUFACTURING METHOD

(71) Applicant: STMICROELECTRONICS S.r.l., Agrate Brianza (IT)

(72) Inventors: Laura Letizia SCALIA, San Giovanni La Punta (IT); Cateno Marco CAMALLERI, Catania (IT); Leonardo FRAGAPANE, Catania (IT)

(73) Assignee: STMICROELECTRONICS S.r.l., Agrate Brianza (IT)

(21) Appl. No.: 18/471,219

(22) Filed: Sep. 20, 2023

(30) Foreign Application Priority Data
Sep. 29, 2022 (IT) 102022000020070

(51) Int. Cl. H01L 29/417; H01L 29/06; H01L 29/08; H01L 29/16; H01L 29/40; H01L 29/66; H01L 29/78

(52) U.S. Cl. CPC H01L 29/41741; H01L 29/0696; H01L 29/0865; H01L 29/1608; H01L 29/401; H01L 29/66068; H01L 29/7802

(57) ABSTRACT

Electronic device, comprising: a semiconductor body having a surface; a body region in the semiconductor body, extending along a main direction parallel to the surface of the semiconductor body; and a source region in the body region, extending along the main direction. The electronic device has, at the body and source regions, a first and a second electrical contact region alternating with each other along the main direction, wherein the first electrical contact region exposes the body region, and the second electrical contact region exposes the source region. The electronic device further comprises an electrical connection layer extending with electrical continuity longitudinally to the body and source regions, in electrical connection with the first and the second electrical contact regions.

### BACKGROUND

### Technical Field

The present disclosure relates to an electronic device and manufacturing method thereof, in particular with improved body-source coupling (short-circuit).

### Description of the Related Art

Electronic devices provided with a Silicon Carbide substrate, with respect to similar devices provided with a silicon substrate, have various advantages such as (but not limited to) low resistance in conduction, low leakage current, high operating frequencies, good switching performances, good structural robustness.

In SiC power MOSFETs, source ohmic contacts are made by silicizing a metal, to form silicides. FIGS. 1A-1D illustrate an exemplary process of forming such ohmic contacts in a MOSFET device 1. FIGS. 1A-1D illustrate a portion of the MOSFET device 1 limitedly to source and body regions whereat it is desired to form respective ohmic contacts 2, 4.

FIG. 1A comprises steps, per se known, of forming or providing a semiconductor body 10, including a substrate 6 and, on the substrate 6, an epitaxial layer 8 (grown by epitaxy). Then, doping species implants are carried out for forming the implanted regions 5 (body wells, with P-type conductivity) and 7 (source regions, with N-type conductivity). The source regions 7 extend within the body wells 5. An annealing step is then carried out for activating the dopants of the body 5 and source 7 implanted regions. There is a need to form an electrical contact (short-circuit) between the body wells 5 and the respective source regions 7. This electrical contact is, in a solution known to the Applicant, provided by forming a conductive layer which provides for forming an ohmic contact (e.g., Silicide of a metal) in direct electrical connection with both the source regions 7 and the body wells 5, as illustrated in FIGS. 1B-1D.

With reference to FIG. 1B, the method then proceeds with the formation of the source 2 and body 4 ohmic contacts. This step includes forming a mask 11, for example of Silicon Oxide, patterned in such a way as to have one or more etching windows 11a which leave surface regions 10′ of the semiconductor body 10 uncovered/exposed whereat it is desired to form the ohmic contacts 2, 4. The mask 11 is patterned, in particular, so as to cover, and therefore protect against successive etching, a portion 7a of the source regions 7 and expose the remaining portion 7b of the source regions 7 through the respective windows 11a.

Then, FIG. 1C, an etching of the semiconductor body is carried out at the surface regions 10′ exposed through the etching windows 11a, completely removing the portions 7b of the source regions, up to reaching the underlying P-type region, belonging to the respective body well 5. This etching is a time-controlled etching. Openings, or trenches, 12 are thus formed in the semiconductor body 10.

Then, FIG. 1D, for forming the ohmic contacts 2, 4, a metal layer (e.g., Ni) is deposited at the trenches 12 (on the bottom and on the lateral walls of the same), and on the mask 11. This step is followed by a suitable annealing at high-temperature (around 1000° C.), to complete the formation of the ohmic contacts 2, 4 (e.g., Nickel Silicide), by chemical reaction between the deposited metal and the Silicon present in the semiconductor body 10. In fact, the deposited metal reacts where it is in contact with the surface material of the semiconductor body 10, forming the ohmic contact.

Successively, the mask 11 is removed and the remaining steps are carried out to complete the formation of the MOSFET device, including (in a manner not illustrated in FIGS. 1A-1D) forming the gate terminal and the source and body electrical contacts (e.g., by depositing a metallization that electrically contacts the source 2 and body 4 ohmic contacts).

As noted from FIG. 1D, the (ohmic) electrical contact 2 between the Silicide layer and the source regions is limited to a lateral portion of the source region 7 (in particular, 7a) exposed through the respective trench 12 (vertical lateral walls), while the electrical contact of the Silicide layer with the body well 5 is more extended and is provided parallel to the surface of the semiconductor body (bottom side of the trench 12). The Applicant has verified that this technical solution is not optimal, since the contact resistance between the ohmic contact (silicide layer) and the source regions 7 may have high values or in any case hardly optimizable. Furthermore, in the context of constant reduction of the dimensions of the electronic devices, the Applicant has verified that the solution of FIGS. 1A-1D is hardly scalable.

The problems discussed above also occur (at least in part) in devices with substrates of a type other than SiC (for example of Silicon, or other semiconductor materials).

### BRIEF SUMMARY

The present disclosure is directed to an electronic device that includes a semiconductor body having a surface and a body region in the semiconductor body, extending along a first direction parallel to the surface of the semiconductor body. There is a source region in the body region, extending along said first direction and a plurality of trenches through the source region and extending into the body region. There is a plurality of raised regions alternative with each trench of the plurality of trenches, each raised region being on the source region. A first electrical contact region is in each trench and a second electrical contact region on each raised region. An electrical connection layer is extending with electrical continuity longitudinally to the body and source regions, in electrical connection with said first and second electrical contact regions in the plurality of trenches and on the plurality of raised portions.

### BRIEF DESCRIPTION OF THE SEVERAL VIEWS OF THE DRAWINGS

For a better understanding of the present disclosure, preferred embodiments are now described, purely by way of non-limiting example, with reference to the attached drawings, wherein:

FIGS. 1A-1D illustrate, in lateral sectional view, intermediate manufacturing steps of a MOSFET device, according to an embodiment which is not an object of the present disclosure;

FIGS. 2-5 illustrate a MOSFET electronic device according to respective views, in accordance with an embodiment of the present disclosure;

FIGS. 6A-6D, 7A-7D, 8A-8D and 9A-9D illustrate manufacturing steps of the MOSFET electronic device of FIGS. 2-5 according to respective views, in accordance with an embodiment of the present disclosure; and

FIGS. 10-13 illustrate a MOSFET electronic device according to respective views, in accordance with a further embodiment of the present disclosure.

### DETAILED DESCRIPTION

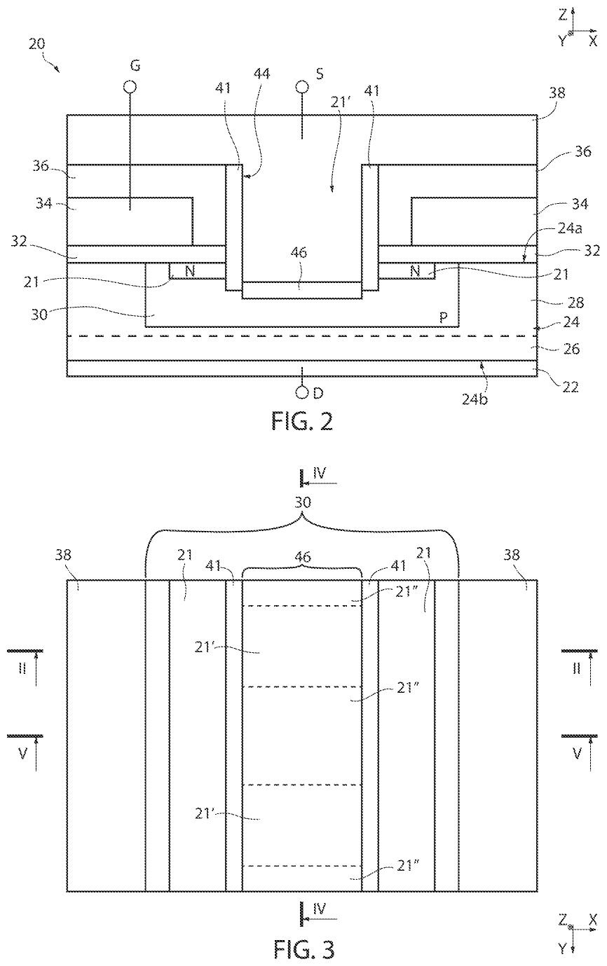

FIG. 2 illustrates, in sectional view in a Cartesian (triaxial) reference system of axes X, Y, Z, a portion of an electronic device 20, in particular a transistor, such as a vertical-channel MOSFET, according to an aspect of the present disclosure. FIG. 2 is a cross-sectional view (on the XZ plane) taken along section line II-II of FIG. 3.

The transistor 20 comprises: a gate electrode G (forming a control terminal) coupeable, in use, to a generator of a biasing voltage V_{GS}; a first conduction terminal S, including a source region 21 (N-type implanted region); and a second conduction terminal D, including a drain region 22. In use, with suitable biasing, a conductive channel of majority carriers (here, electrons) is established between the source region 21 and the well region 22.

In greater detail, the transistor 20 comprises a semiconductor body 24, in particular of SiC, having a first and a second face 24a, 24b opposite to each other along the direction of the Z axis. In particular, in the present embodiment, the term “semiconductor body” means a structural element or solid body that may comprise one or more epitaxial layers grown on a base substrate. In particular, FIG. 2 illustrates a semiconductor body 24 including a substrate 26 having an epitaxially-grown structural layer 28 extending thereon, acting as a drift layer. The substrate 26 has a first conductivity, here of the N-type, and doping for example comprised between 1·10¹⁸ cm⁻³ and 5·10¹⁹ cm⁻³. The structural layer 28 has the first conductivity, here of the N-type, and lower doping than that of the substrate 26, for example comprised between 1·10¹⁴ cm⁻³ and 5·10¹⁶ cm⁻³.

According to an aspect of the present disclosure, the semiconductor body 24 is of Silicon Carbide (SiC), such as for example 4H—SiC or 3C—SiC (other SiC polytypes are however possible and contemplated within the scope of the present disclosure).

Alternatively, and according to a further aspect of the present disclosure, the semiconductor body 24 is of Silicon or other semiconductor material.

The gate electrode G extends on the first face 24a of the semiconductor body 24; a body region 30, having a second conductivity opposite to the first conductivity (here, therefore, a P-type implanted region), extends into the semiconductor body 24 (more particularly, into the structural layer 28) at (facing) the first face 24a; the source region 21, having the first conductivity (N), extends into the body region 30 at (facing) the first face 24a; and the drain metallization 22 extends at the second face 24b of the semiconductor body 24. The transistor 20 is therefore of the vertical-conduction type (i.e., the conductive channel extends along a main direction which is along the Z axis).

The gate electrode G includes a gate conductive terminal 34, and a gate dielectric 32. The gate conductive terminal 34 extends on the gate dielectric 32, in a per se known manner.

An insulating, or dielectric, layer 36 extends on the gate terminal 34 and is, in particular, of silicon dioxide (SiO₂) or silicon nitride (SiN) with a thickness, measured along the Z axis, comprised between 0.5 μm and 1.5 μm. Furthermore, in proximity of the insulating layer 36 there extends a source metallization 38, for example Aluminum with a thickness, measured along the Z axis, comprised between 0.5 μm and 2 μm.

The source metallization 38 extends up to contacting the source region 21 and the body region 30, in a manner better described hereinbelow. To allow the electrical contact, a conductive region or layer 46 (in particular for forming an ohmic contact) extends between the source metallization 38 and the source 21 and body 30 regions. The ohmic contact layer 46 is, in one embodiment of a metal Silicide, such as for example a Silicide of Ni, Ti, Co, Pt. In the case of a semiconductor body 24 of SiC, the layer 46 is preferably provided by said Silicide; in the case of a semiconductor body 25 of silicon or other material other than SiC, the layer 46 is of said Silicide or of a metal suitably chosen to provide the ohmic contact.

An interface layer to allow the ohmic contact, not illustrated, also of a Silicide of a metal (e.g., Nickel), may be present between the semiconductor body 24 and the drain metal layer 22.

As illustrated in FIG. 2, the source metallization 38 extends into a trench 44 through the insulating layer 36, the gate dielectric 32 and penetrates in part within the semiconductor body 24 at the first face 24a and at the source 21 and body 30 regions. A protection layer 41, of insulating or dielectric material, for example SiO₂ or SiN, is optionally present along the lateral walls of the trench 44, and has the function of improving the electrical insulation (along X) between the source metallization 38 and the gate conductive terminal 34.

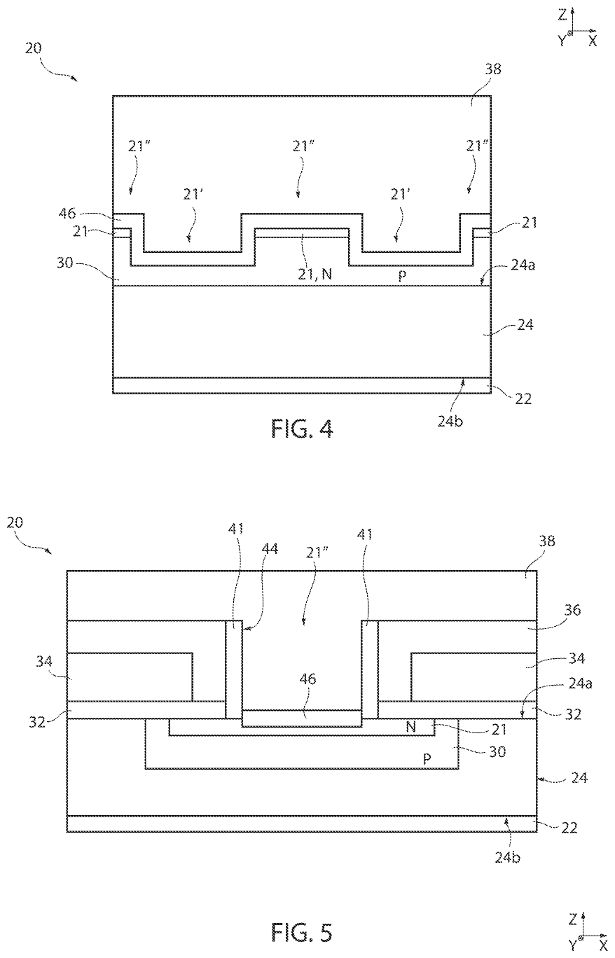

In the section of FIG. 2 only the electrical contact between the source metallization 38 and the body region 30 is represented; the electrical contact between the source metallization 38 and the source region 21 is provided in a different section of the transistor 20, as better described below and represented for example in FIG. 4 or FIG. 5.

FIG. 3 illustrates the transistor 20 in top-plan view (on the XY plane), limitedly to portions of the transistor 20 and technical characteristics of the same which are useful for the understanding of the present disclosure (in particular, at the active area which accommodates, in use, the conductive channel).

As noted, the gate electrode G (in particular, the gate conductive terminal 34), the implanted body regions 30 and the source regions 21 of the transistor 20 have, in this view, a strip shape and each extend along a respective main direction which is parallel to the Y axis. In other words, in at least one portion of the transistor 20, in top-plan view, the gate conductive terminal 34, the implanted body region 30 and the source region 21 have a respective rectangular shape, with main extension (major side) along Y and secondary extension (minor side) along X.

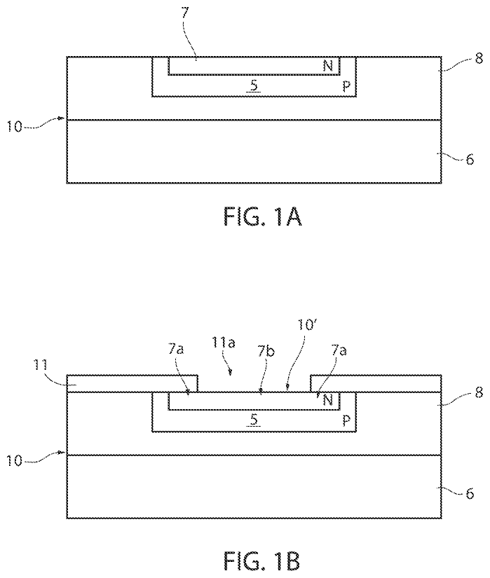

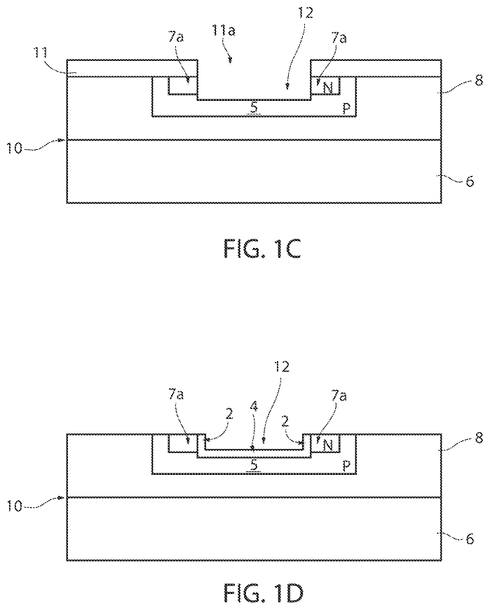

As illustrated in FIG. 3, the strip of the source region 21 has, alternating with each other along its main extension, a portion 21′ having the trench 44 (similar to the trench 12 of FIG. 1) extending thereat and a portion 21″ having no trench 44. As said with reference to FIG. 2, the trench 44 extends, in the portion 21′, in depth into the semiconductor body 24 from the first face 24a; the trench 44 extends completely through the source region 21, ending within the underlying body region 30 (which accommodates or contains this source region 21). At the portion 21″, the source region 21 extends seamlessly facing the first face 24a of the semiconductor body 24, the trench 44 being absent. The regions 21′ and 21″ alternate with each other (i.e., they are arranged sequentially) along the main extension direction of the source strip (here, along the direction of the Y axis).

At the region 21′, the trench 44 is completely contained within the source region 21 and has an extension, transversely to the main direction of the source strip (i.e. along the X axis), lower than the corresponding extension of the source region 21 along the same X axis. In this manner, the source region 21 is never completely interrupted from an electrical point of view.

From FIG. 3 the extension and the shape of the ohmic contact layer 46 may also be appreciated. The ohmic contact layer 46 extends in the form of a continuous strip at the source region 21 and is (in top-view on the XY plane) at least in part superimposed on the source region 21. At the portion 21′ (which exposes the body region 30 through the trench 44), the ohmic contact layer 46 extends in electrical contact with the body region 30; at the portion 21″ (which exposes the source region 21), the ohmic contact layer 46 extends in direct electrical contact with the source region 21 (see FIG. 4 in this regard). The ohmic contact layer 46 extends with electrical continuity between the portion 21′ and the portion 21″, in electrical contact with both portions 21′ and 21″. In this manner, the ohmic contact layer 46 electrically connects the source region 21 with the body region 30 which accommodates this source region 21 (short-circuiting the body region 30 with the respective source region 21).

FIG. 4 illustrates, in sectional view on the YZ plane, the alternation of the portions 21′ and 21″. The section of FIG. 4 is taken along section line IV-IV of FIG. 3, longitudinally to the source strip 21.

FIG. 5 illustrates the transistor 20 in cross-sectional view on the XZ plane, along section line V-V of FIG. 3, that is at the portion 21″ wherein the ohmic contact layer 46 is in direct electrical contact with the source region 21. In this context it is observed that the sectional view of FIG. 2 illustrates the transistor 20 at the portion 21′, where the trench 44 is present and the ohmic contact layer 46 is in electrical contact with the body region 30.

Optionally, in one embodiment, the transistor 20 further comprises a P+ implanted region within each body region 30, in direct electrical contact with the respective body region 30, and below the respective source region 21. This P+ implanted region has the same type of dopants as the body region 30 (here, P-type) and a greater dopant concentration than the dopant concentration of the body region 30. The P+ implanted region has the function of improving the electrical contact between the ohmic contact layer 46 and the body region 30. To this end, the trench 44 extends through the source region 21 up to reaching the P+ implanted region and ends within the P+ implanted region. The ohmic contact layer 46 extends (in the portion 21′) in direct electrical contact with the P+ implanted region and in electrical contact with the body region 30 through this P+ implanted region.

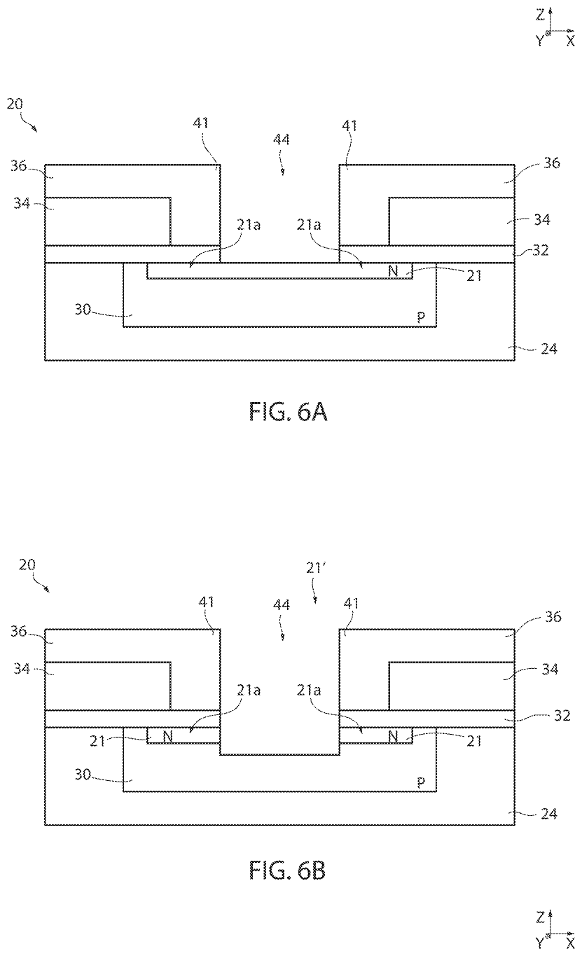

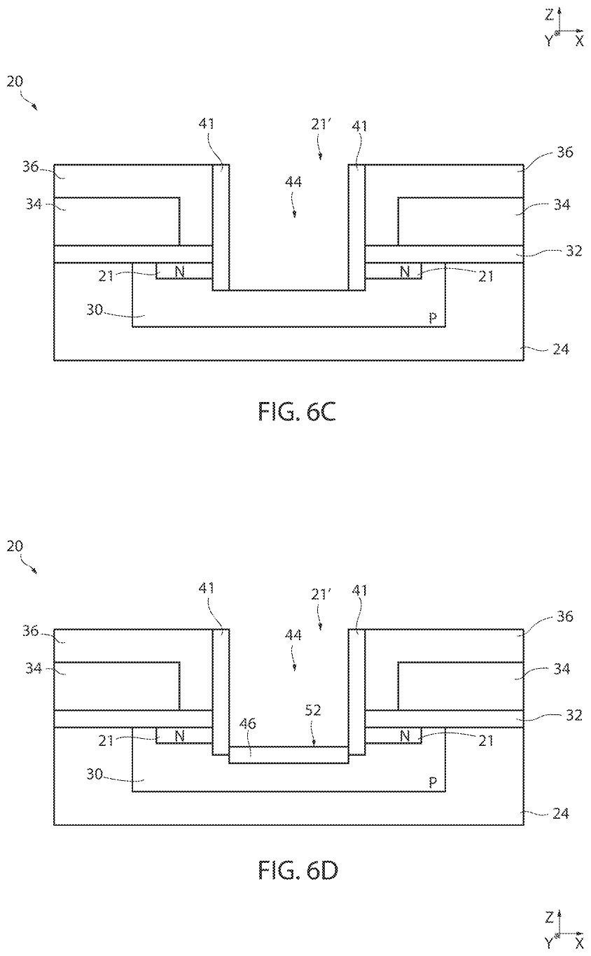

Manufacturing steps of the transistor 20 are now illustrated, with joint reference to FIGS. 6A-6D, 7A-7D, 8A-8D, 9A-9D.

FIGS. 6A-6D, 7A-7D, 8A-8D, 9A-9D illustrate a portion of the transistor 20 (here, the MOSFET of FIGS. 2-5), limitedly to source and body regions whereat it is desired to form the ohmic contact layer 46.

The teaching of the present disclosure is generally applied to devices of different type, for example VMOS (“Vertical-channel MOS”), DMOS (“Diffused MOS”), CMOS (“Complementary MOS”), FET, trench-FET.

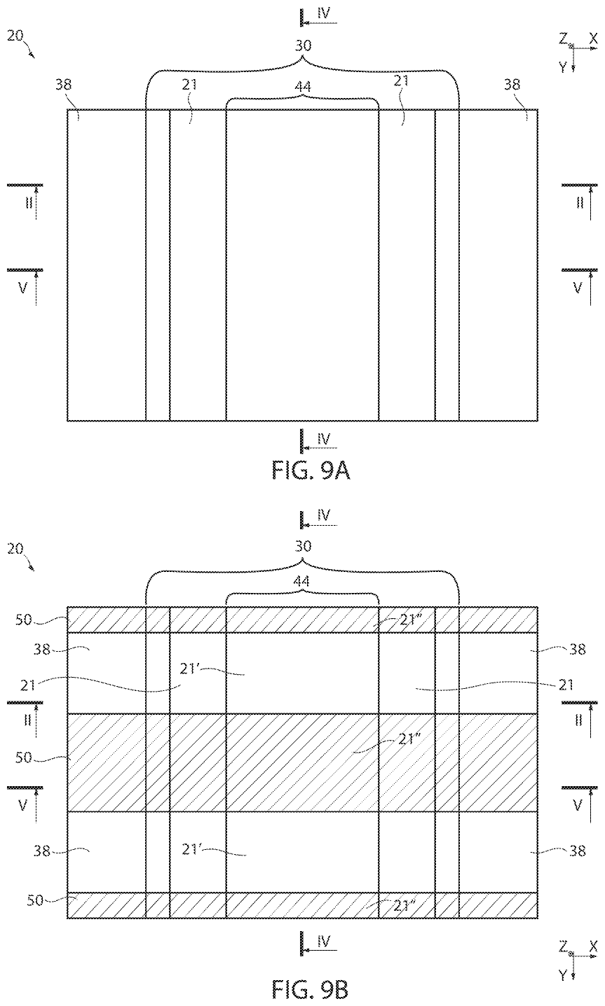

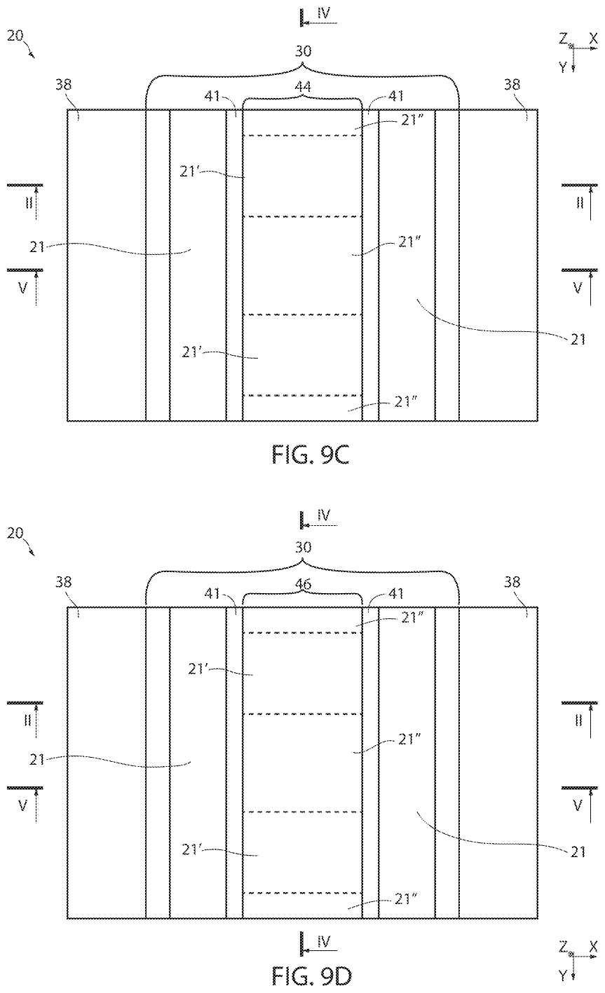

FIGS. 6A-6D illustrate the transistor in cross-sectional view on the XZ plane, along scribe line II-II of FIG. 3 (this scribe line is shown in FIGS. 9A-9XD), that is where the trenches 44 are formed to form the body electrical contact.

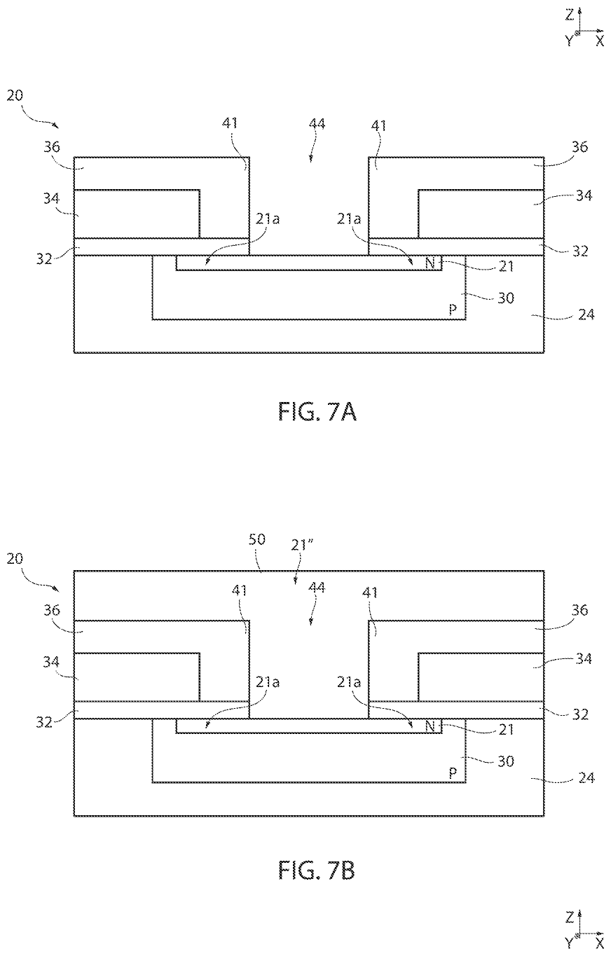

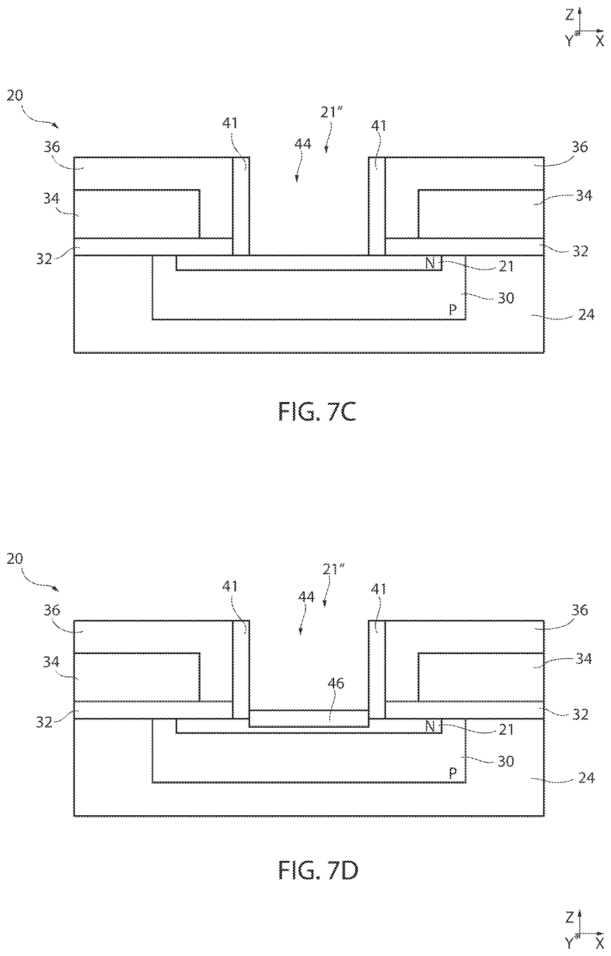

FIGS. 7A-7D illustrate the transistor in cross-sectional view on the XZ plane, along scribe line V-V of FIG. 3 (this scribe line is shown in FIGS. 9A-9D), that is where the source electrical contact is formed.

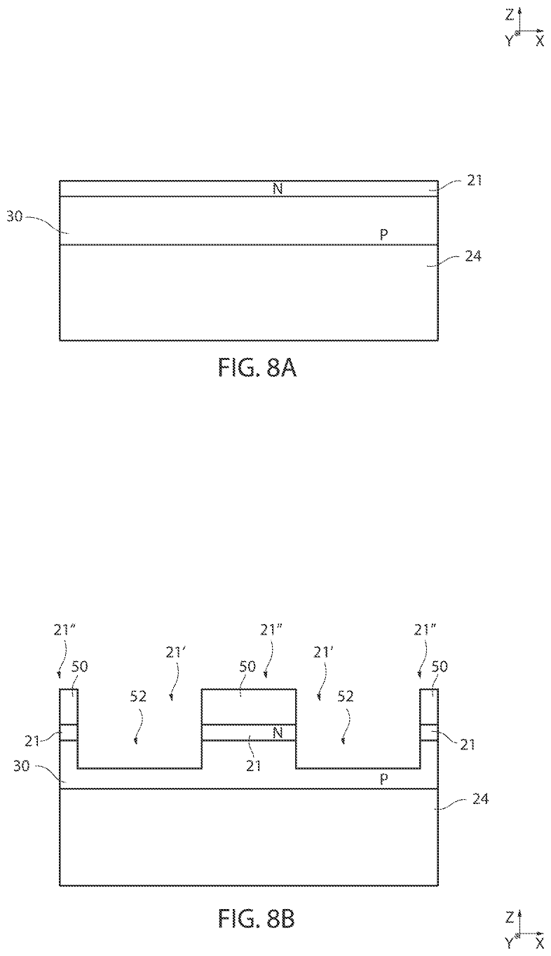

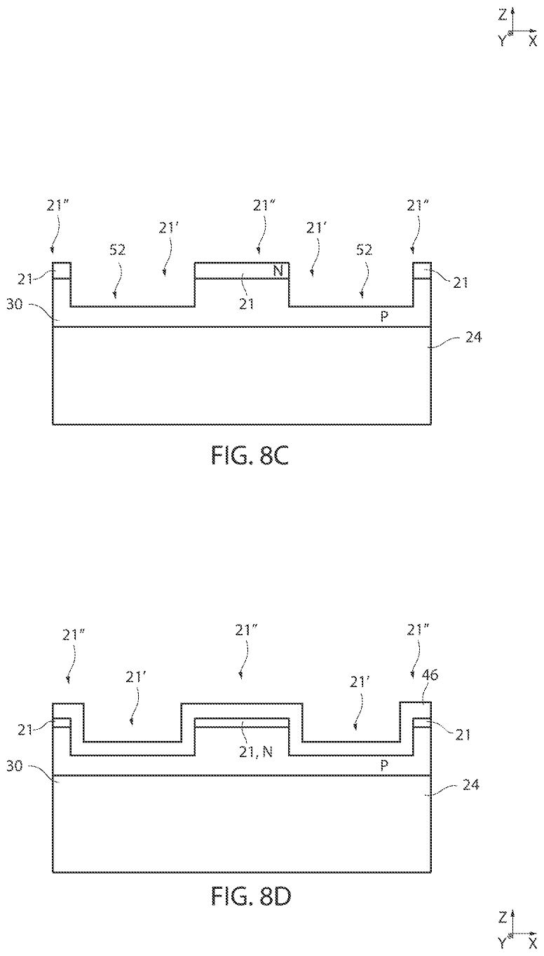

FIGS. 8A-8D illustrate the transistor in cross-sectional view on the YZ plane, along scribe line Iv-Iv of FIG. 3 (this scribe line is shown in FIGS. 9A-9D), that is longitudinally to the strip of the source region 21.

FIGS. 9A-9D illustrate the transistor in top-plan view on the XY plane, (similarly to FIG. 3).

FIGS. 6A, 7A, 8A and 9A illustrate the transistor 20 in an intermediate manufacturing step, after manufacturing steps per se known and therefore not described in detail. In analogy to what has been described with reference to FIGS. 1A and 1B, after having arranged or formed the semiconductor body 24 (e.g., of SiC), the implants are carried out to form the body region 30 (by implanting P-type doping species) and the source region 21 in the body region 30 (implanting N-type doping species). Optionally, the P+ implanted region is also formed within the body region 30. An annealing (e.g., between 1400 and 2000° C.) is carried out to activate the implanted dopants. Then, the gate electrode G is formed by depositing the gate dielectric 32 and forming the gate conductive region 34 (e.g., of N-doped polysilicon). The insulating layer 36 is then formed above the gate conductive region 34. Successively, by a masked etching step, the trench 44 is formed which exposes, as already previously mentioned, the surface 24a of the semiconductor body 24 at the source region 21. Side portions 21a of the source region 21 are covered (and therefore protected from etching) by respective portions of the insulating layer 36 and of the gate dielectric 32 (in other words, the trench 44 has extension, along X, lower than the corresponding extension of the source region 21).

Then, FIGS. 6B, 7B, 8B, 9B, an etching step of the semiconductor body 24 is carried out at selective portions exposed through the trench 44, in particular at the regions 21′ previously discussed. To this end, a mask 50 (e.g., of resist) is formed which covers the semiconductor body 24 at the regions 21″ (FIG. 7B), leaving exposed the semiconductor body 24 at the regions 21′ (FIG. 7A).

A time-controlled etching is then carried out, to remove portions of the semiconductor body where the resist mask 50 is not present. In this regard, it is observed that, along the section of FIG. 6B, the insulating layer 36 may not be covered by the resist mask 50, in particular in case the etching chemical solution used is selective with respect to the material of the semiconductor body 24 (of SiC, in the illustrated example); in other words, the etching chemical solution is chosen in such a way as to remove selective portions of the semiconductor body 24 but not the material of the insulating layer 36.

As illustrated in FIGS. 6B and 8B, a further trench 52 is thus formed which completely traverses the source region 21 in the portion 21′, reaching the underlying body region 30 and ending within the body region 30. At the portion 21″, protected by the resist mask 50, trench 52 is not formed (FIGS. 7B and 8B).

Then, FIGS. 6C, 7C, 8C and 9C, an optional step of forming the protection layer 41 (lateral spacers) is carried out at the (vertical) lateral walls of the trench 44 and, where present, of the trench 52. The protection layer 41 has the function of restoring the electrical insulation properties which could be reduced by the damage to the insulating layer 36 following the preceding etching. The protection layer 41 is of insulating or dielectric material, such as SiO₂ or SiN, and has, along the X axis, a thickness comprised between 70 and 200 nm.

Then, FIGS. 6D, 7D, 8D and 9D, the method proceeds with the formation of the source and body ohmic contact 46.

This step includes forming a deposition mask (not illustrated), for example of Silicon Oxide, patterned in such a way as to leave uncovered the portions 21′ and 21″ whereat it is desired to form the ohmic contact layer 46.

A metal layer (typically Ni, Ti, or a Ni/Ti combination) is successively deposited above the mask and at the first face 24a in the portions 21′ and 21″ exposed through the deposition mask. This step is followed by a suitable high-temperature annealing (rapid thermal process, between 800° C. and 1150° C., more particularly between 900° C. and 1150° C., for a time interval from 1 minute to 120 minutes). This allows the ohmic contacts to be formed, by chemical reaction between the deposited metal and the Silicon present in the semiconductor body 24 (which, in this embodiment, is of SiC). In fact, the deposited metal reacts where it is in contact with the surface material of the semiconductor body 24, forming the ohmic contact (e.g., of Ni₂Si in case the metal is Ni). As it observed from FIGS. 8D and 9D, the ohmic contact layer 46 is continuous longitudinally to the source strip 21 (along Y), electrically connecting the body region 30 and the source region 21.

Successively, the metal that did not react during Silicide formation and that extends above the deposition mask used, is removed. This mask is also removed.

Finally, the remaining steps are carried out to complete the formation of the transistor 20, including the formation of the conductive layer 38 to electrically contact the ohmic contact layer 46 through the trench 44, obtaining the transistor 20 of FIGS. 2-5.

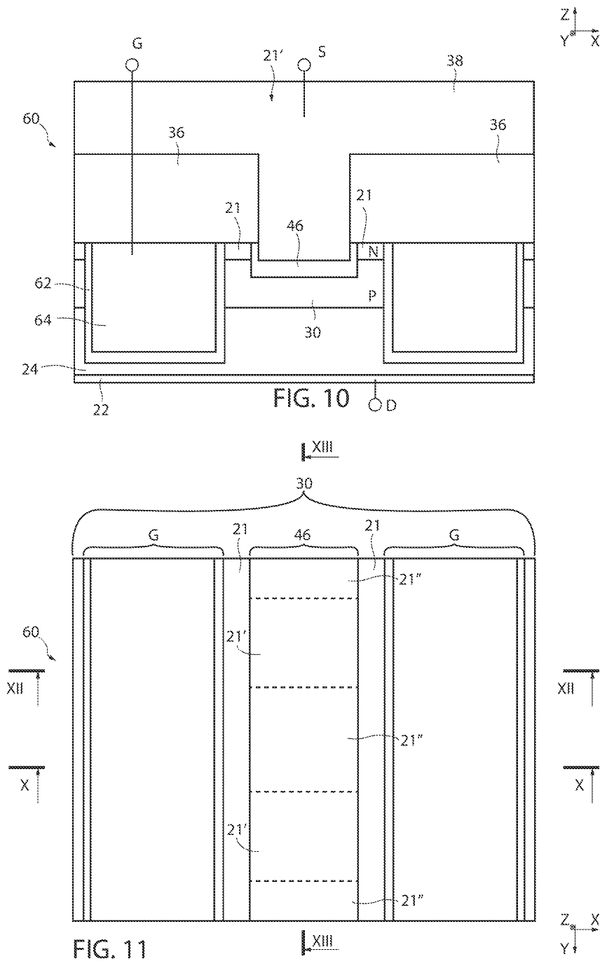

The present disclosure is also applicable to trench-gate devices. FIGS. 10-13 illustrate a transistor 60 of the trench-gate type, wherein the gate electrode G extends in depth into the semiconductor body, laterally to the source region 21. The gate electrode G comprises a gate dielectric 62 that completely surrounds, and electrically insulates, a gate conductive terminal 64. Common elements of the transistor 60 with the transistor 20 are identified with the same reference numbers.

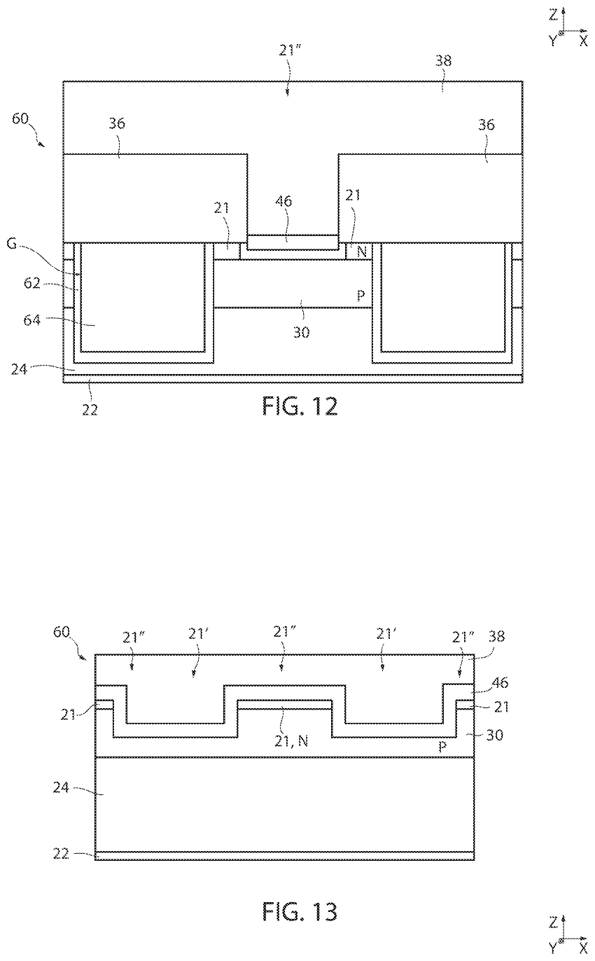

FIG. 11 illustrates the transistor 60 in top-plan view, on the XY plane. FIG. 10 illustrates the transistor 60 in cross-section, on the XZ plane, along scribe line X-X of FIG. 11. FIG. 12 illustrates the transistor 60 in cross-section, on the YZ plane, along scribe line XII-XII of FIG. 11. FIG. 13 illustrates the transistor 60 in cross-section, on the XZ plane, along scribe line XIII-XIII of FIG. 11.

The transistor 60 has, in analogy to what has been previously described, the regions 21′ and 21″ alternating with each other along, longitudinally to, the source strip (FIG. 12), according to what has already been described with reference to FIG. 4.

Since the gate conductive terminal 64 extends into the semiconductor body 24, the protection layer 41 is absent.

From the foregoing, the advantages that the present disclosure affords are evident.

In particular, according to the present disclosure, the source and body contact areas are optimized and maximized, to provide a short-circuit therebetween. Furthermore, since the formation of the layer 46 which implements this contact is self-aligned (in fact the insulating layer 36, which is a structural layer of the device 20, 60, is used to define the Silicide formation regions), the present disclosure does not jeopardize a reduction of the dimensions of the device 20, 60.

Finally, it is clear that modifications and variations may be made to what has been described and illustrated herein, without thereby departing from the scope of the present disclosure, as defined in the attached claims.

In particular, the present disclosure has been described and illustrated in the attached Figures with reference to a single body region 30 and a single source region 21; however, it is known that an electronic device typically comprises a plurality of body regions 30 and respective source regions 21, which extend (in plan view) in the form of a strip parallel to each other and at a distance from each other. Such a device further comprises a respective plurality of gate electrodes G, which extend (in plan view) in the form of a strip between two respective body/source regions.

An electronic device (20; 60), may be summarized as including a semiconductor body (24) having a surface (24a); a body region (30) in the semiconductor body (24), extending along a main direction (Y) parallel to the surface (24a) of the semiconductor body (24); and a source region (21) in the body region (30), extending along said main direction (Y), wherein the electronic device (20; 60) has, at the body (30) and source (21) regions, a first (21′) and a second (21″) electrical contact region alternating with each other along said main direction (Y), wherein the first electrical contact region (21′) exposes the body region (30), and the second electrical contact region (21″) exposes the source region (21), said electronic device (20, 60) further including an electrical connection layer (46) extending with electrical continuity longitudinally to the body (30) and source (21) regions, in electrical connection with said first and second electrical contact regions (21′, 21″).

Said first and second electrical contact regions (21′, 21″) may be contiguous to each other along said main direction (Y).

The electrical connection layer (46) may be a Silicide of a metal.

The first electrical contact region (21′) may include a trench (52) which extends in depth into the semiconductor body (24) from said surface (24a) completely through the source region (21) and ending within the body region (30).

At the second electrical contact region (21″), the source region (21) may face the surface (24a) of the semiconductor body (24).

The electrical connection layer (46) may extend on the surface (24a) of the semiconductor body (24) in direct contact with the source region (21) at the second electrical contact region (21″).

The electrical connection layer (46) may be superimposed, in top-plan view, on the source (21) and body (30) regions.

The semiconductor body may be of Silicon Carbide, SiC.

The electronic device (20; 60) may further include a gate electrode (G) of the trench-or planar-type.

A method of manufacturing an electronic device (20; 60), may be summarized as including the steps of: forming, in a semiconductor body (24) having a surface (24a), a body region (30) which extends along a main direction (Y) parallel to the surface (24a) of the semiconductor body (24), and a source region (21) which extends in the body region (30) along said main direction (Y); forming, in the semiconductor body (24) at the body (30) and source (21) regions, a first (21′) and a second (21″) electrical contact region alternating with each other along said main direction (Y), wherein the first electrical contact region (21′) exposes the body region (30), and the second electrical contact region (21″) exposes the source region (21); forming an electrical connection layer (46) which extends with electrical continuity longitudinally to the body (30) and source (21) regions, in electrical connection with said first and second electrical contact regions (21′, 21″).

The method may further include the steps of: forming a gate electrode (G); forming an electrical insulation layer (36) on the gate electrode (G); and forming a first trench (44) through the electrical insulation layer (36) at said source region (21), exposing a corresponding portion of the surface (24a) having the source region (21) faced thereto, wherein the step of forming the first electrical contact region (21′) may include forming, within the first trench (44), a second trench (52) in the semiconductor body (24) from said surface (24a), the second trench (52) extending completely through the source region (21) and ending within the body region (30).

The method may further include, prior to the step of forming the second trench (52), the step of forming an etching mask (50) which extends into the first trench (44) covering the second electrical contact region (21″) and leaving the first electrical contact region (21′) uncovered.

The semiconductor body may include Silicon, wherein the step of forming the electrical connection layer (46) may include depositing a metal layer within the first and the second trenches (44, 52) at the first and the second electrical contact regions (21′, 21″), and carrying out a thermal process for forming a Silicide of said metal layer.

The electrical connection layer (46) may be formed superimposed, in top-plan view, on the source (21) and body (30) regions.

The method may further include, after the step of forming the first trench (44), the step of depositing a protection layer (41) of insulating or dielectric material along lateral walls of said first trench (44).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a semiconductor body having a surface;
a body region in the semiconductor body, extending along a first direction parallel to the surface of the semiconductor body; and
a source region in the body region, extending along said first direction,
a plurality of trenches through the source region and extending into the body region;
a plurality of raised regions alternative with each trench of the plurality of trenches, each raised region being on the source region;
a first electrical contact region in each trench;
a second electrical contact region on each raised region;
an electrical connection layer extending with electrical continuity longitudinally to the body and source regions, in electrical connection with said first and second electrical contact regions in the plurality of trenches and on the plurality of raised portions.

2. The electronic device according to claim 1, wherein said first and second electrical contact regions are contiguous to each other along said first direction.

3. The electronic device according to claim 1, wherein the electrical connection layer is a metal silicide.

4. The electronic device according to claim 1, wherein the electrical connection layer extends on the surface of the semiconductor body in direct contact with the source region at the second electrical contact region.

5. The electronic device according to claim 1, wherein the semiconductor body is Silicon Carbide (SiC).

6. A method of manufacturing an electronic device, comprising:
forming, in a semiconductor body having a surface, a body region which extends along a first direction parallel to the surface of the semiconductor body, and a source region which extends in the body region along said first direction;
forming, in the semiconductor body at the body and source regions, a first and a second electrical contact region alternating with each other along said first direction, by forming a plurality of trenches at the first electrical contact region that expose the body region, and forming a plurality of raised portions alternating between the trenches at the second electrical contact region that expose the source region;
forming an electrical connection layer which extends with electrical continuity longitudinally to the body and source regions, in electrical connection with said first and second electrical contact regions.

7. The method according to claim 6, further comprising:
forming a gate electrode;
forming an electrical insulation layer on the gate electrode; and
forming a first trench of the plurality of trenches through the electrical insulation layer at said source region, exposing a corresponding portion of the surface having the source region faced thereto,
wherein forming the first electrical contact region comprises forming, within the first trench, a second trench of the plurality of trenches in the semiconductor body from said surface, the second trench extending completely through the source region and ending within the body region.

8. The method according to claim 7, further comprising, prior to forming the second trench, forming an etching mask which extends into the first trench covering the second electrical contact region and leaving the first electrical contact region uncovered.

9. The method according to claim 7, wherein the semiconductor body comprises Silicon, and wherein forming the electrical connection layer comprises:
depositing a metal layer within the first and the second trenches at the first and the second electrical contact regions, and
carrying out a thermal process for forming a Silicide of said metal layer.

10. The method according to claim 6, wherein the electrical connection layer is formed superimposed, in top-plan view, on the source and body regions.

11. The method according to claim 10, further comprising, after forming the first trench, the depositing a protection layer of insulating or dielectric material along lateral walls of said first trench.

12. A device, comprising:
a semiconductor layer;
a body region of a first conductivity type in the semiconductor layer;
a plurality of source regions of a second conductivity type spaced from each other along a first direction;
a plurality of first openings through the source region that expose portions of the body layer;
a gate electrode that overlaps the body region and the plurality of source regions;
a second opening in the gate electrode that exposes the plurality of source regions and the portions of the body region, the second opening having a first dimension in the first direction and a second dimension in a second direction that is transverse to the first direction;
a first insulating layer that is on the gate electrode and in the second opening;
a connection electrode that is in the second opening, in contact with the portions of the body layer, and in contact with the plurality of source region.

13. The device of claim 12, comprising a second insulating layer on sidewalls of the first insulating layer and in the second opening.

14. The device of claim 13 wherein the connection electrode is between opposing sides of the second insulating layer.

15. The device of claim 14 comprising a third insulating layer between the gate electrode and the body region and between the gate electrode and the plurality of source regions.

16. The device of claim 15 wherein sidewalls of the gate electrode are spaced from each other along the second direction by a third dimension that is greater than the first dimension.

17. The device of claim 16 wherein sidewalls of the first insulating layer in the second opening are spaced from each other along the second direction by a fourth dimension that is greater than the first dimension and is less than the second dimension.
